(19) United States
(12) Patent Application Publication
(10) Pub. No.: US 2008/0106842 A1
(43) Pub. Date: May 8, 2008

(54) MOUNTING DEVICE, PLASMA PROCESSING APPARATUS AND PLASMA PROCESSING METHOD

(75) Inventors: Hiroharu ITO, Nirasaki-shi (JP); Kenichi Kato, Nirasaki-shi (JP); Takehiro Ueda, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/934,313

(22) Filed: Nov. 2, 2007

Related U.S. Application Data
(60) Provisional application No. 60/888,238, filed on Feb. 5, 2007.

(30) Foreign Application Priority Data
Nov. 6, 2006 (JP) 2006-300923

(51) Int. Cl. H01L 21/683; B44C 1/22; C23C 16/00; H01L 21/306

(52) U.S. Cl. 361/234; 118/723 R; 156/345.51; 216/67; 427/534

(57) ABSTRACT

A mounting device includes a mounting body for sustaining a target object to be processed thereon; an electrostatic chuck disposed on the mounting body and having an electrode layer interposed between insulating layers, and the electrostatic chuck serving to electrostatically attract and hold the target object on a surface of the insulating layer by a electrostatic force generated between the electrode layer and the target object by a voltage applied to the electrode layer. Herein, an electrostatic chuck layer, which is one of the insulating layers on the side of a top surface of the electrode layer, is made of a plasma spray coating of yttrium oxide, which is formed by a plasma spraying, having a thickness of about 200 μm to 280 μm, and the electrostatic chuck layer has a surface roughness dependent on a particle diameter of the yttrium oxide used in the plasma spraying.

### FIELD OF THE INVENTION

The present invention relates to a mounting device having an electrostatic chuck for electrostatically attracting and holding a target object such as a semiconductor wafer, and also relates to a plasma processing apparatus equipped with the mounting device and a plasma processing method.

### BACKGROUND OF THE INVENTION

In general, a mounting device for use in a plasma processing apparatus for performing a plasma process such as an etching or a chemical vapor deposition (CVD) employs an electrostatic chuck instead of a vacuum chuck as a means for sustaining a substrate on the mounting device.

The electrostatic chuck is disposed on a surface portion of a mounting body. The electrostatic chuck has a sheet shape and includes a thin electrode embedded in an insulating layer. The electrostatic chuck functions to attract the substrate and hold it on the surface thereof by an electrostatic force generated by, e.g., a DC voltage applied to the electrode.

When performing a vacuum process, e.g., a plasma process on the substrate loaded on the mounting device, a temperature control gas (backside gas) is supplied between a rear surface of the substrate and the electrostatic chuck, whereby a heat applied from a plasma to the substrate is radiated through the temperature control gas to the mounting body, so that the temperature of the substrate is maintained at a specific temperature level.

Between an end of a plasma processing for one substrate and a beginning of next plasma processing for another one, some reaction products floating in the plasma processing apparatus stick to the surface of the mounting device. For the reason, in, e.g., a parallel plate type plasma processing apparatus, the surface of the mounting device is cleaned by using a plasma formed from a cleaning gas without placing a substrate on the mounting device. At this time, by setting the mounting device (lower electrode) to be in an electrically floating state, an impact force of ions, which are ionized from the cleaning gas, on the surface of the electrostatic chuck is moderated, so that a deterioration of surface roughness of the electrostatic chuck can be suppressed (Japanese Patent Laid-open Application No. 2006-019626 (paragraphs 0040-0047, FIG. 2).

Since, however, the insulating layer constituting the conventional electrostatic chuck is made of a thermally sprayed Al₂O₃ coating, the thermally sprayed Al₂O₃ coating would be damaged by the plasma if the cleaning is performed without placing the substrate on the electrostatic chuck (i.e., if a so-called waferless cleaning is performed). As a result, aluminum (Al) particles would be dispersed inside the plasma processing apparatus, and the interior of the plasma processing apparatus would be contaminated with Al. The Al particles may be transferred onto the wafer, causing a metal contamination thereon.

Meanwhile, Japanese Patent Laid-open Application No. 2004-349612 (paragraphs 0041-0042, paragraph 0052, FIG. 1) discloses using a thermally sprayed Y₂O₃ coating as an insulating layer constituting the electrostatic chuck, wherein the thickness of the thermally sprayed Y₂O₃ coating is set to be 10 μm to 100 μm.

Electrostatic chucks can be classified into two types: one is a Johnsen-Rahbek type that attracts and holds a substrate by an electrostatic force generated between a substrate and a surface of the electrostatic chuck; and the other is a Coulomb type that attracts and holds a substrate by the electrostatic force generated between a substrate and an electrode in an insulating layer. As for the Coulomb type electrostatic chuck, though a current value flowing in the electrode is small and the attractive force is stabilized, a voltage applied to the electrode is high, ranging from about 2.5 kV to 4.0 kV. Further, if plasma cleaning (waterless cleaning) is performed on the surface of the electrostatic chuck as described above, it is likely that pin holes are formed in the electrostatic chuck (in the thermally sprayed coating) or the thickness of the coating is locally reduced due to the influence of voids or particles present in the thermally sprayed coating.

Accordingly, if the waterless cleaning process is performed in case that the thickness of the thermally sprayed Y₂O₃ coating is 10 μm to 100 μm, pin holes would be formed in the coating of the thin thickness, or the thickness of the coating at some parts would be extremely reduced. If the high voltage is applied to the Coulomb type electrostatic chuck in such state, a dielectric breakdown is caused in a short time.

Further, since the surface of the electrostatic chuck roughens as the repetition number of the plasma cleaning increases, an amount of a backside gas leaking from between the rear surface of the substrate and the surface of the mounting device increases when the substrate is mounted on the mounting device. As a result, uniformity of a temperature distribution deteriorates or the temperature distribution changes with a lapse of time. However, theses problems are not discussed in Japanese Patent Laid-open Application No. 2004-349612 at all.

### SUMMARY OF THE INVENTION

In view of the foregoing, the present invention provides a mounting device that is capable of preventing a dielectric breakdown of an electrostatic chuck over a long period of time, without causing a metal contamination of a target object. Further, the present invention provides a plasma processing apparatus equipped with the mounting device and a plasma processing method.

In accordance with a first aspect of the present invention, there is provided a mounting device including: a mounting body for sustaining a target object to be processed thereon; an electrostatic chuck disposed on the mounting body and having an electrode layer interposed between insulating layers and the electrostatic chuck serving to electrostatically attract and hold the target object on a surface of an insulating layer by an electrostatic force generated between the electrode layer and the target object by a voltage applied to the electrode layer.

Herein, an electrostatic chuck layer, which is one of the insulating layers on the side of a top surface of the electrode layer, is made of a thermally sprayed coating of yttrium oxide, which is formed by a plasma spraying, having a thickness of about 200 μm to 280 μm, and the electrostatic chuck layer has a surface roughness dependent on a particle diameter of the yttrium oxide used in the plasma spraying.

It is preferable that an average surface roughness of the electrostatic chuck layer is about 0.6 μm to 0.8 μm. Further, a surface of the electrostatic chuck layer is cleaned by a plasma in a state where no target object is placed thereon. Further, the voltage applied to the electrode layer is equal to or greater than about 2.5 kV.

In accordance with a second aspect of the present invention, there is provided a plasma processing apparatus including: an airtight processing vessel; the mounting device of the first aspect; a vacuum evacuation unit for evacuating the processing vessel to vacuum; and a plasma processing unit for performing a plasma process on the target object by generating a plasma in the processing vessel. Herein, a surface of the electrostatic chuck is cleaned in a state where no target object is placed on the mounting device.

In accordance with a third aspect of the present invention, there is provided a plasma processing method including: performing a plasma processing on a target object after electrostatically attracting and holding the target object on the mounting device of the first aspect; and cleaning a surface of the electrostatic chuck by a plasma after unloading the target object from the mounting device.

In accordance with the mounting device of the present invention, the electrostatic chuck layer is constituted by a thermally sprayed Y₂O₃ coating layer, thus a plasma resistance is increased, and metal contaminants do not need to be considered. Further, a thickness of the electrostatic chuck layer is set to be an 200 μm to 280 μm, thus even if a high voltage is applied to an electrode layer, an occurrence of a dielectric breakdown with respect to the electrostatic chuck can be prevented. Therefore, the above electrostatic chuck layer can be applied to a coulomb type electrostatic chuck. Especially, a creation of pin holes inside the electrostatic chuck layer or a local decrease of the thickness of the layer is unlikely to occur even in case the plasma cleaning is performed while no substrate is placed on the mounting device, and the occurrence of the dielectric breakdown can be prevented over a long period of time by setting the thickness as above.

Further, the thermally sprayed coating layer has a surface roughness depending on the particle diameter of the yttrium oxide used in the plasma spraying so that the thermally sprayed coating layer having a surface roughness suitable for a plasma process can be obtained. The present inventors have found that the surface of the thermally sprayed Y₂O₃ coating layer exposed by the plasma has an average surface roughness (Ra) ranging from about 0.7 μm to 0.8 μm. Thus, by forming the thermally sprayed Y₂O₃ coating layer such that its average surface roughness is in the range from about 0.6 μm to 0.8 μm, it is possible to suppress a change of a surface state with a lapse of time, even if the plasma cleaning is repeatedly performed on the thermally sprayed Y₂O₃ coating layer. As a result, an effect of a temperature control by a backside gas is stable, and a temperature of a substrate during the process is also stable.

### BRIEF DESCRIPTION OF THE DRAWINGS

The objects and features of the present invention will become apparent from the following description of embodiments, given in conjunction with the accompanying drawings, in which:

FIG. 1 is a vertical cross sectional view showing an exemplary plasma processing apparatus having a mounting device in accordance with an embodiment of the present invention;

FIG. 2 sets forth a vertical cross sectional view of the mounting device in accordance with the embodiment of the present invention;

FIG. 3 presents a schematic view to describe an electrostatic attraction;

FIGS. 4A to 4D provide cross sectional views to describe a manufacturing process of the mounting device shown in FIG. 2;

FIG. 5 offers an explanatory diagram to describe a test result of a plasma resistance;

FIG. 6 is a characteristic graph showing a relationship between a thickness of a thermally sprayed Al₂O₃ coating and a withstanding voltage;

FIG. 7 presents a characteristic graph showing a relationship between a thickness of a thermally sprayed Y₂O₃ coating and a withstanding voltage; and

FIG. 8 sets forth a plan view showing measurement points on the surface of the mounting device.

### DETAILED DESCRIPTION OF THE EMBODIMENTS

Embodiments of the present invention will now be described with reference to the accompanying drawings which form a part hereof.

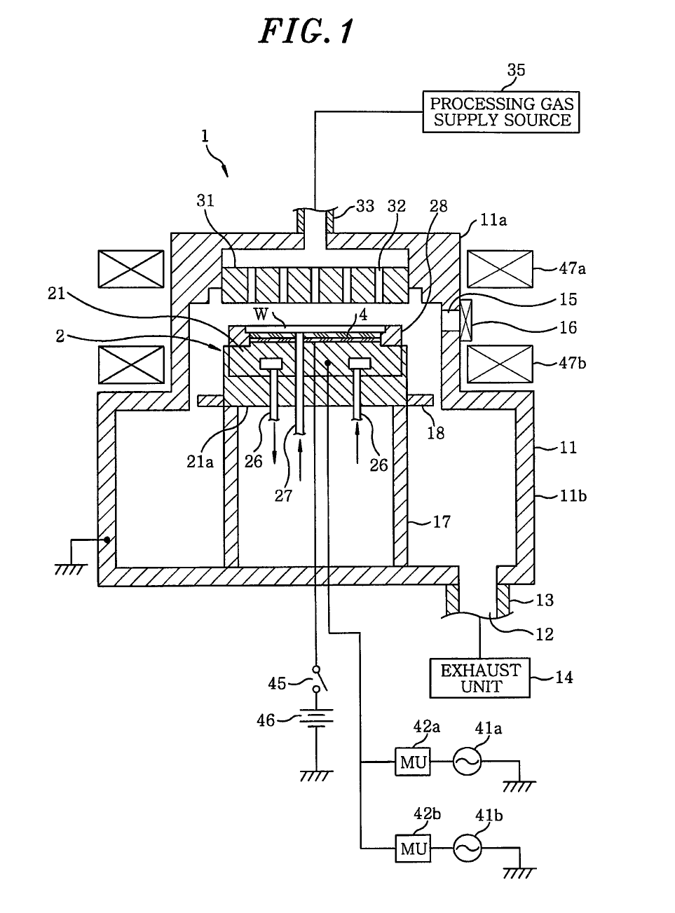

In FIG. 1, a mounting device in accordance with the present invention is applied to a plasma processing apparatus used as an etching apparatus. FIG. 1 shows an exemplary RIE (Reactive Ion Etching) plasma processing apparatus 1. The plasma processing apparatus 1 includes a processing vessel 11 configured as, e.g., an air-tightly sealed vacuum chamber; a mounting device 2 disposed at a lower central portion in the processing vessel 11; and an upper electrode 31 disposed above the mounting device 2 to face the mounting device 2 in parallel.

The processing vessel 11 includes a cylindrical upper room 11a and a cylindrical lower room 11b having a larger diameter than that of the upper room 11a. The upper room 11a and the lower room 11b communicate with each other, and the entire processing vessel 11 is air-tightly sealed. The mounting device 2, the upper electrode 31, and so forth are accommodated in the upper room 11a, and a supporting case 17 including piping and the like is accommodated in the lower room 11b to support the mounting device 2. A gas exhaust unit 14 is connected via a gas exhaust line 12 to a gas exhaust port 13 provided in a bottom surface of the lower room 11b.

A pressure control unit (not shown) connected to the gas exhaust unit 14 maintains the internal pressure of the processing vessel 11 at a desired vacuum level by vacuum evacuating the entire processing vessel 11 in response to a signal from a control unit (not shown). Meanwhile, a loading/unloading port 15 for a wafer W is provided at a sidewall of the upper room 11a, and the loading/unloading port 15 is opened or closed by a gate valve 16. Further, the processing vessel 11 is made of a conductive member such as aluminum, and it is grounded.

The upper electrode 31 has a hollow shape and is configured as a gas showerhead having in the bottom surface thereof a number of gas injection openings 32 which are, for example, uniformly distributed in the upper electrode, for supplying and distributing a processing gas and a cleaning gas into a processing vessel 11. A gas inlet line 33 is disposed at a center of the top surface of the upper electrode 31, and the upper side of the gas inlet line 33 is connected to a processing gas supply source 35. The processing gas supply source 35 has a mass flow controller (not shown) for controlling a supply/stop of the processing gas and an increase/decrease of the flow rate of the processing gas to be supplied into the processing vessel 11. Further, by fixing the upper electrode 31 at the sidewall of the upper room 11a, a conductive path is formed between the upper electrode 31 and the processing vessel 11.

Further, two multi-pole ring magnets 47a and 47b are disposed around the upper room 11a to be located above and under the loading/unloading port 15, respectively. Each of the multi-pole ring magnets 47a and 47b has a plurality of anisotropic columnar segment magnets attached to a ring-shaped magnetic casing in such a manner that magnetic pole directions of every two neighboring columnar segment magnets are arranged to be opposite to each other. Therefore, magnetic force lines are formed between the neighboring columnar segment magnets, and a magnetic field is formed around the peripheral region of a processing space between the upper electrode 31 and the mounting body (lower electrode) 21, thereby confining a plasma in the processing space. These multi-pole ring magnets 47a and 47b may be omitted.

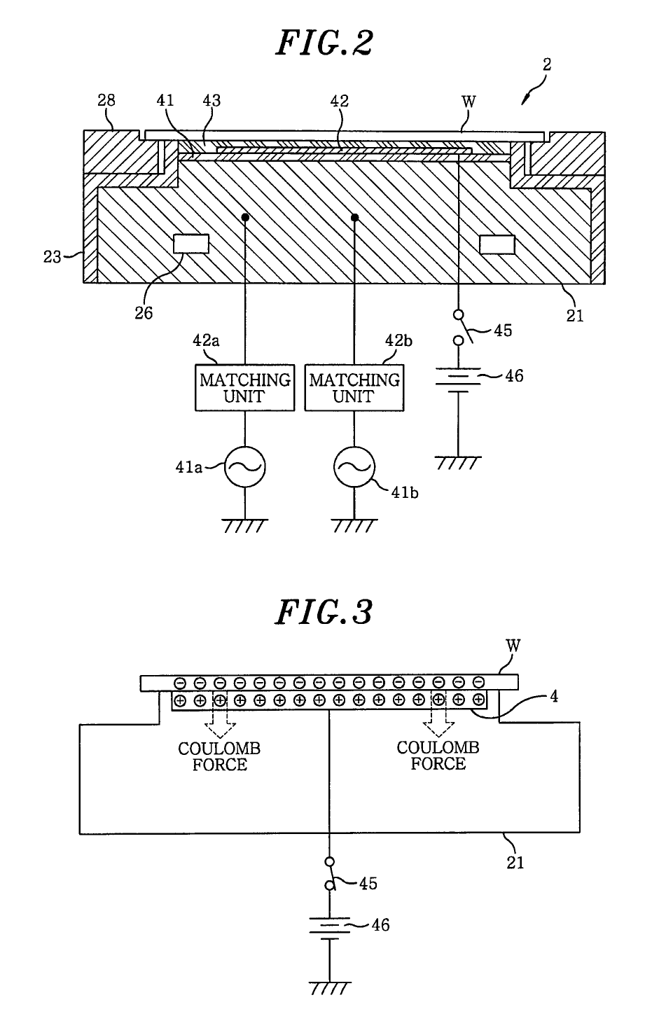

Now, the mounting device 2 will be described in detail. The mounting device 2 includes, as shown in FIGS. 1 and 2, a mounting body 21 made of, e.g., aluminum serving as a lower electrode and having a top surface of which central portion protrudes higher than the peripheral portion thereof; a sheet-shaped electrostatic chuck 4 to be described later provided on top of the mounting body 21 and a focus ring 28 disposed to surround the electrostatic chuck 4.

The mounting device 21 is fixed on a support 21a disposed on the supporting case 17. The focus ring 28 functions to control a plasma state outside the periphery of the wafer W. For example, the focus ring 28 extends diffusion area of the plasma to be lager than an area of the wafer W, thus improving in-plane uniformity in the etching rate of the wafer W. A baffle plate 18 is provided at an outside of a lower portion of the support 21a to surround the support 21a. The baffle plate 18 functions as a rectifying plate for adjusting the flow of the processing gas by allowing the processing gas in the upper room 11a to flow into the lower room 11b through a gap between the baffle plate 18 and the wall portion of the upper room 11a.

Further, as shown in FIG. 2, the outer peripheral surface of the mounting body 21 is covered with a thermally sprayed Y₂O₃ coating layer 23 formed by a thermal spraying of Y₂O₃. The thermally sprayed Y₂O₃ coating layer 23 is integrated as one body with the electrostatic chuck 4.

The electrostatic chuck 4 has a sheet structure in which a thermally sprayed Al₂O₃ coating layer 41, an electrode layer 42, and a thermally sprayed Y₂O₃ coating layer 43 are deposited in this order from the bottom, wherein the thermally sprayed Al₂O₃ coating layer 41 is formed on a top surface of the mounting body 21 by, e.g., a thermal spraying of alumina, the electrode layer 42 is made of a thermally sprayed coating layer of tungsten (W) formed by a thermal spraying of W, and the thermally sprayed Y₂O₃ coating layer 43 is formed by a thermal spraying of Y₂O₃. The manufacturing method for this electrostatic chuck 4 will be explained later in detail.

The electrode layer 42 of the electrostatic chuck 4 is connected via a switch 45 to a high-voltage DC power supply 46 which is a power supply unit. If a high DC voltage is applied to the electrode layer 42 from the high-voltage DC power supply 46, the wafer W is electrostatically attracted to and held on the top surface (mounting surface) of the electrostatic chuck 4 by a Coulomb force (electrostatic polarization force) generated between the wafer W and the electrode layer 42, as shown in FIG. 3.

Moreover, a first high frequency power supply 41a for supplying a high frequency power of, e.g., about 100 MHz and a second high frequency power supply 41b for supplying a high frequency power of a lower frequency than that from the first frequency power supply 41a, e.g., about 3.2 MHz are connected to the mounting body 21 via matching units 42a and 42b, respectively. The high frequency power supplied from the first high frequency power supply 41a serves to convert the processing gas into a plasma as will be described later, while the high frequency power supplied from the second high frequency power supply 41b serves to attract ions in the plasma toward the surface of the wafer by applying a bias power to the wafer W.

Further, a coolant path 26 through which a coolant flows is formed inside the mounting body 21. By the circulation of the coolant through the coolant path 26, the mounting body 21 is cooled, whereby the wafer W loaded on the mounting surface is cooled down to a desired temperature level. In addition, there is also formed a heat transfer medium supply line 27 for supplying a heat transfer medium, e.g., He gas (backside gas) to the rear surface side of the wafer W through the mounting body 21 and the electrostatic chuck 4. The heat transfer medium supply line 27 has a function of transferring a heat, which is applied from the plasma to the wafer W, to the mounting body 21, to thereby maintain the temperature of the wafer W at a set temperature level. Further, elevation pins that enable a conveyance of the wafer to a transfer arm (not shown) are installed inside the mounting body 21.

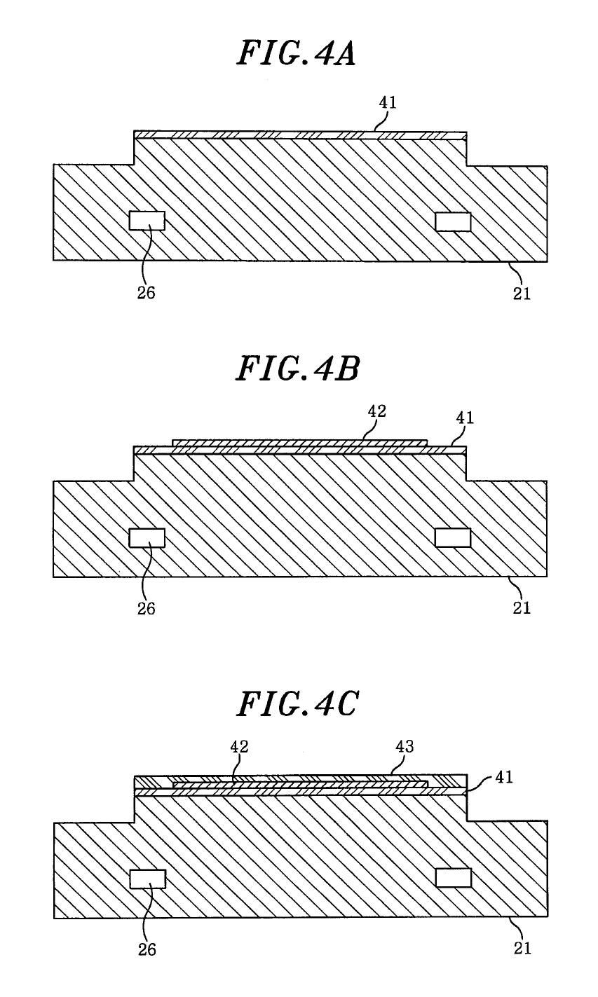

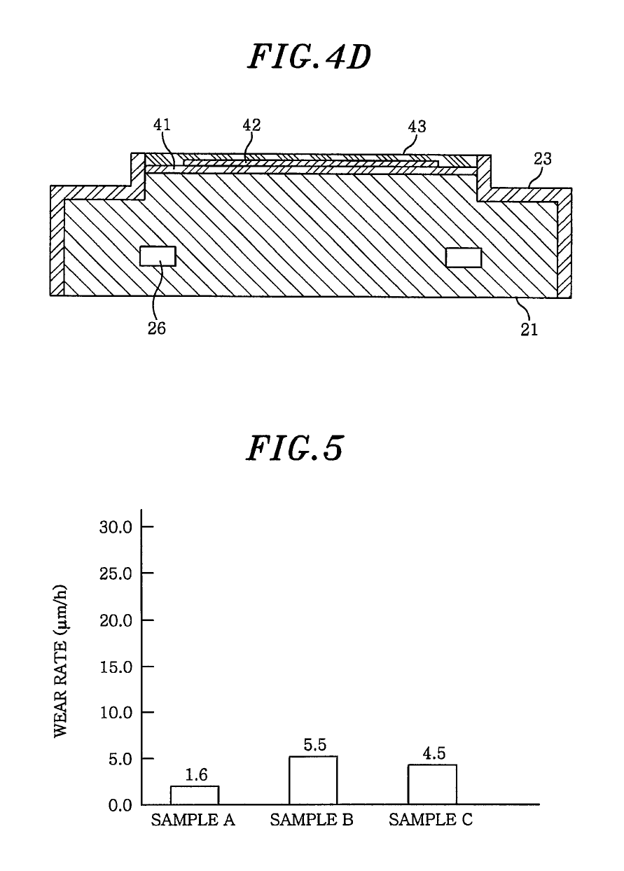

Hereinafter, the method for manufacturing the mounting device 2 will be described with reference to FIGS. 4A to 5. First, a mounting body 21 provided with a coolant path 26 and a heat transfer medium supply line 27 (not shown) is prepared. With the mounting body 21 heated up to, e.g., 150° C., alumina is thermally sprayed after masking a peripheral portion of the top surface of the mounting body 21, lower than a central portion thereof. As a result, a thermally sprayed Al₂O₃ coating layer 41 having a thickness of, e.g., 450 μm is formed. Thereafter, the thermally sprayed Al₂O₃ coating layer 41 is polished until its thickness becomes, e.g., 300 μm (see FIG. 4A).

Then, after masking the Al₂O₃ except for its portion on which the electrode layer 42 is to be formed, tungsten is thermally sprayed, whereby the electrode layer 42 having a thickness of, e.g., 50 μm is formed (see FIG. 4B). Subsequently, in a state the mounting body 21 is heated up to, e.g., 150° C., yttrium oxide having a particle diameter of, e.g., 10 μm to 20 μm is plasma sprayed by employing a plasma spraying method, whereby a thermally sprayed Y₂O₃ coating layer 43 having a thickness of, e.g., 450 μm is formed. The plasma spraying method refers to a coating method for spraying a material on the surface of a target object by accelerating the material by a plasma.

Thereafter, the thermally sprayed Y₂O₃ coating layer 43 is polished until its thickness decreases to, e.g., 200 μm to 280 μm; preferably, 250 μm (see FIG. 4C). As an example of the polishing method, the mounting body 21 is fixed on a turn table, and while rotating the turn table, a rotational grinder having diamond polishing particles is rotated and moved with respect to the mounting body 21, whereby the thermally sprayed Y₂O₃ coating layer 43 is polished. Here, the lower limit of the thickness of the thermally sprayed Y₂O₃ coating layer 43 is set to equal to 200 μm in order to prevent a dielectric breakdown of a Coulomb type electrostatic chuck for a long period of time. For example, there can be used a Coulomb type electrostatic chuck to which a voltage of 4.0 kV is applied. In such case, by setting the lower limit as above, an occurrence of the dielectric breakdown can be prevented over a long period of time, even if the waterless cleaning is repeatedly performed.

Furthermore, in case of an electrostatic chuck of the kind to which a voltage of 2.5 kV is applied to the electrode layer 42, about 4.0 kV, for example, may be applied in a shipping test while considering a voltage margin. By setting the lower limit as described above, the occurrence of dielectric breakdown can be prevented even when a high voltage, such as 4.0 kV, is applied, as can be seen from data of a withstanding voltage test to be described later.

Further, the thermally sprayed Y₂O₃ coating layer 43 formed by the plasma spraying has a surface roughness that depends on the particle diameter of the yttrium oxide. Specifically, an average surface roughness (Ra) of the thermally sprayed Y₂O₃ coating layer 43 is, e.g., about 0.6 μm to 0.8 μm. The present inventors have found that the surface of the thermally sprayed Y₂O₃ coating layer 43 is exposed by the plasma and has an average surface roughness (Ra) ranging from about 0.7 μm to 0.8 μm. Thus, by forming the thermally sprayed Y₂O₃ coating layer 43 such that its average surface roughness is in the range from about 0.6 μm to 0.8 μm, it is possible to suppress a change of a surface state with a lapse of time, even if the plasma cleaning is repeatedly performed on the thermally sprayed Y₂O₃ coating layer 43. Through the above-described series of processes, the electrostatic chuck 4 having the electrode layer 42 interposed between the thermally sprayed Al₂O₃ coating layer 41 and the thermally sprayed Y₂O₃ coating layer 43 is formed as one body with the mounting device 21, as illustrated in FIG. 4C.

Subsequently, after masking the top surface portion of the electrostatic chuck 4, yttrium oxide is plasma sprayed to the outer peripheral surface of the mounting device 21 in a state the mounting device 21 is heated up to, e.g., 150° C., whereby a thermally sprayed Y₂O₃ coating layer 23 having a thickness of, e.g., about 400 μm is formed (See FIG. 4D). By this process, the thermally sprayed Y₂O₃ coating layer 23 is integrated as one body with the thermally sprayed Al₂O₃ coating layer 41 and the thermally sprayed Y₂O₃ coating layer 43. Thereafter, the mask material is removed from the electrostatic chuck 4.

By configuring the plasma processing apparatus 1 as described above, a pair of parallel plate type electrodes made up of the mounting device (lower electrode) 21 and the upper electrode 31 are formed in the processing vessel 11 (upper room 11a) of the plasma processing apparatus 1.

Now, an operation in accordance with the embodiment of the present invention will be described. First, the gate valve 16 is opened, and a wafer W is loaded into the processing vessel 11 by the transfer arm (not shown) through the loading/unloading port 15 and is placed on the mounting device 2. Then, the transfer arm is withdrawn, and after closing the gate valve 16, the processing vessel 11 is depressurized by the gas exhaust unit 14 such that the internal pressure of the processing vessel 11 reaches a specific pressure level, e.g., less than or equal to about 26.7 Pa (200 mTorr).

Thereafter, through the gas injection openings 32 of the gas showerhead, a processing gas, e.g., C₄F₈ gas is supplied into a space above the mounting device 2 at a specific flow rate. At this time, a high DC voltage ranging from about 2.5 kV to 4.0 kV, e.g., about 2.5 kV is applied from the high-voltage DC power supply 46 to the electrode layer 42 of the electrostatic chuck 4, whereby the wafer W is electrostatically attracted to and held on the top surface (mounting surface) of the electrostatic chuck 4 by a Coulomb force (electrostatic polarization force) generated between the wafer W and the electrode layer 42, as shown in FIG. 3.

Then, a high frequency power is applied from the first high frequency power supply 41a to the mounting body (lower electrode) 21. This high frequency wave flows from the mounting body 21 to the processing vessel 11 via the upper electrode 31 and flows to the ground, whereby a high frequency electric field is formed in a processing gas atmosphere. Here, magnetic force lines are formed between the neighboring columnar segment magnets, and a magnetic field is formed around the peripheral region of a processing space between the upper electrode 31 and the mounting body (lower electrode) 21 by the multi-pole ring magnets 47a and 47b, by the presence of the magnetic field, electrons are made to drift, which in turn causes a magnetron discharge.

As a result of the magnetron discharge, the processing gas is converted to a plasma, and ions or radicals are generated. Thereafter, a specific high frequency power is applied from the second high frequency power supply 41b to the mounting body (lower electrode) 21, so that a self-bias voltage is generated thereby an etching of the wafer W loaded on the mounting body 2 is carried out.

In the above-described plasma processing apparatus 1, reaction products generated during the etching of the wafer W float in the processing gas atmosphere inside the processing vessel 11. Thus, when the etched wafer W is unloaded from the processing vessel 11, those reaction products stick to the surface of the mounting device 2, i.e., the surface of the electrostatic chuck 4 where no wafer W is located. Thus, there arises a need to remove the reaction products stuck to the mounting device 2 periodically.

Now, a method for cleaning the plasma processing apparatus for the purpose of removing the reaction products will be explained. For example, after an etching process of a final wafer W of one lot is completed and the wafer W is unloaded from the processing vessel 11, the gate valve 16 is closed, and the processing vessel 11 is depressurized by the gas exhaust unit 14 such that the internal pressure of the processing vessel 11 reaches a specific pressure level, e.g., equal to or less than about 26.7 Pa (200 mTorr). Thereafter, through the gas injection openings 32 of the gas showerhead, a cleaning gas, e.g., O₂ gas and SF₆ gas are supplied into the space above the mounting device 2 at a specific flow rates, e.g., 800 sccm for each.

The cleaning gas is also converted into the plasma in a manner described above, excepting that, at this time, the second high frequency power supply 41b is turned off, that is, the mounting body (lower electrode) 21 is set to be in an electrically floating state to thereby remove the reaction products deposited on the mounting surface of the mounting device 2. The removed reaction products (dusts) are discharged out of the processing vessel 11 by the gas exhaust unit 14. Through this process, the reaction products deposited on the mounting surface of the mounting device 2 are removed.

In accordance with the embodiment described above, since the electrostatic chuck 4 of the mounting device 2 is made of the thermally sprayed Y₂O₃ coating layer 43, metals such as aluminum do not disperse in the processing vessel 11. Further, since the thickness of the thermally sprayed Y₂O₃ coating layer 43 ranges from about 200 μm to 280 μm, a dielectric breakdown of the thermally sprayed Y₂O₃ coating layer 43 is unlikely to occur even if a high voltage greater than or equal to about 2.5 kV is applied to the electrode layer 42.

Accordingly, the configuration of the present invention can be applied to a Coulomb type electrostatic chuck. Further, since the thermally sprayed Y₂O₃ coating layer 43 has a higher plasma resistance than that of the thermally sprayed Al₂O₃ coating layer, a creation of pin holes inside the electrostatic chuck (the thermally sprayed Y₂O₃ coating layer 43) or a local decrease of the thickness of the thermally sprayed Y₂O₃ coating layer 43 is unlikely to occur, even in case the plasma cleaning is performed while no wafer W is placed on the mounting device 2.

Thus, owing to this high resistance feature of the thermally sprayed Y₂O₃ coating layer 43 along with the effect of setting its thickness to be in the above-specified range, a dielectric breakdown can be prevented over a long period of time. Furthermore, since the thermally sprayed Y₂O₃ coating layer 43 has a surface roughness suitable for the plasma process, it does not suffer from a local decrease of its thickness even in case the plasma cleaning is repeatedly performed on it. Thus, it is believed that no wafer contamination takes place.

(Experiments)

Now, experiments for investigating effects of the present invention will be described.

(Evaluation Test for Plasma Resistance)

A sample A having a thermally sprayed Y₂O₃ coating on a surface thereof, a sample B having a thermally sprayed Al₂O₃ coating on a surface thereof, and an alumina ceramic plate (sample C) were installed on a wafer W. Then, the wafer W was loaded on a mounting table of a plasma processing apparatus, and the samples A, B, and C were exposed to a plasma under the following process conditions to measure wear rates of the samples A, B and C. The results are provided in FIG. 5:

Internal pressure of processing vessel: 5.3 Pa (40 mTorr);

Processing gas: CF₄/Ar/O₂=80/160/20 sccm;

High frequency power: 1400 W.

As shown in FIG. 5, the wear rate of the sample A was 1.6 μm/h; the wear rate of the sample B was 5.5 μm/h; and the wear rate of the sample C was 4.5 μm/h. As revealed from the results, the thermally sprayed Y₂O₃ coating has a higher plasma resistance than those of the thermally sprayed Al₂O₃ coating and the alumina ceramic plate.

(Evaluation Test for Dielectric Breakdown)

Before evaluating a thermally sprayed Y₂O₃ coating, a relationship between a film thickness of a thermally sprayed Al₂O₃ coating and a dielectric withstanding voltage was investigated in a reference test. Used in the reference test was a sample obtained by forming a thermally sprayed Al₂O₃ coating on an electrode on a surface of an insulating substrate. The test was conducted by disposing the sample in a vacuum atmosphere and measuring a voltage at which a dielectric breakdown of the thermally sprayed Al₂O₃ coating takes place.

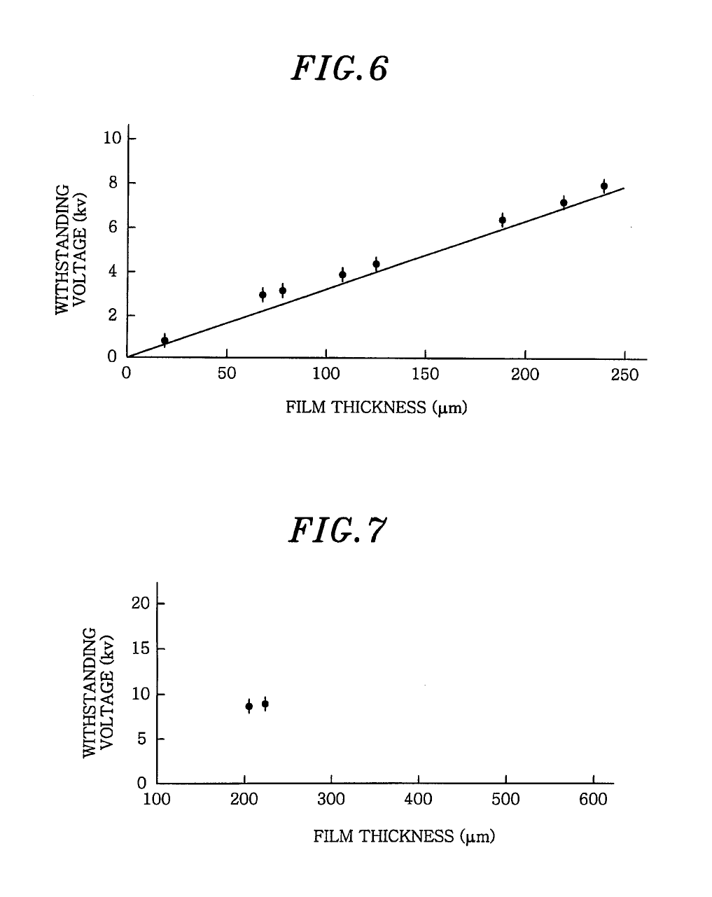

This test was performed while varying the thickness of the thermally sprayed Al₂O₃ coating, and the results are provided in FIG. 6. As clearly seen from the results, with a thickness of about 10 μm to 100 μm as disclosed in Japanese Patent Laid-open Application No. 2004-349612, a dielectric breakdown occurs if a voltage of 4 kV is applied, so the coating in this thickness range cannot be used in a Coulomb type electrostatic chuck. Further, it is also apparent that even in case the application voltage is set to be a lower level, the coating in this thickness range cannot be used in the process of performing the waterless cleaning, either.

Based on the reference test, same experiment was performed on Y₂O₃ samples of which thickness were 200 μm and 220 μm, respectively, and the results are provided in FIG. 7. As can be seen from the results, if an application voltage is set as, e.g., 4 kV, the margin of the dielectric withstanding voltage has a margin of two.

(Evaluation Test for Wafer Contamination)

### A: EXAMPLE

By using the plasma processing apparatus 1 shown in FIG. 1, plasma cleaning was performed on the surface of the mounting device 2 without loading a wafer W on the mounting device 2. The plasma cleaning was performed under the following conditions:

Internal pressure of processing vessel: 26.7 Pa (200 mTorr);

Cleaning gas: O₂/SF₆=800/800 sccm;

First high frequency power: 750 W;

Second high frequency power: 0 W;

Processing time: 25 seconds.

After the cleaning process was completed, a contamination processing of the processing vessel 11 was performed while mounting a bare wafer W on the mounting device 2 in the processing vessel 11. This contamination processing includes contamination steps 1 to 4 that are performed in sequence. Below, process conditions of the contamination steps 1 to 4 are specified:

(Contamination Step 1)

Internal pressure of processing vessel: 2.6 Pa (20 mTorr);

Processing gas: CF₄/CH₃/He=150/250/400 sccm;

First high frequency power: 450 W;

Second high frequency power: 75 W;

Processing time: 5 seconds;

(Contamination Step 2)

Internal pressure of processing vessel: 1.3 Pa (10 mTorr);

Processing gas: HBr/O₂=330/3 sccm;

First high frequency power: 250 W;

Second high frequency power: 250 W;

Processing time: 10 seconds;

(Contamination Step 3)

Internal pressure of the processing vessel: 2.6 Pa (20 mTorr);

Processing gas: HBr/O₂/N₂/He=42/8/12/60 sccm;

First high frequency power: 0 W;

Second high frequency power: 250 W;

Processing time: 10 seconds;

(Contamination Step 4)

Internal pressure of processing vessel: 13 Pa (100 mTorr);

Processing gas: O₂=140 sccm;

First high frequency power: 750 W;

Second high frequency power: 0 W;

Processing time: 10 seconds.

After completing the contamination processing described above, the bare wafer W was unloaded from the processing vessel 11, and a quantitative analysis of atoms attached on the surface of the bare ware W was conducted.

### B: COMPARATIVE EXAMPLE

A surface of the electrostatic chuck was cleaned under the same conditions as those for the Example except that a thermally sprayed Al₂O₃ coating layer was used in the mounting device 2 shown in FIG. 2, instead of the thermally sprayed Y₂O₃ coating layer 43. Then, a bare wafer W was mounted on the mounting device 2 in the processing vessel 11, and a contamination processing was performed under the same conditions as those for the Example. After completing the contamination processing, the bare wafer W was unloaded from the processing vessel 11, and a quantitative analysis of atoms attached on the surface of the bare wafer W was conducted.

(Results and Implication)

The analysis results are provided in Table 1 (on the unit of ×10¹⁰ atoms/cm²).

TABLE 1

| | Fe | Cr | Ni | Na | Cu | Al | Y |
|---|---|---|---|---|---|---|---|
| Example | 4.3 | 1.8 | 0.1 | 4.1 | 0.2 | 8.2 | 0.2 |
| Comparative | 11 | 2.5 | 0.3 | 16 | 0.2 | 100 | 0.0 |
| example | | | | | | | |

As revealed from the results, Al was 100×10¹⁰ atoms/cm² when the thermally sprayed Al₂O₃ coating was used, while its amount decreases to 8.2×10¹⁰ atoms/cm² when the thermally sprayed Y₂O₃ coating was used. Accordingly, by using the thermally sprayed Y₂O₃ coating, the amount of Al contaminants decreases greatly, in comparison with the case of using the thermally sprayed Al₂O₃ coating. Since it is considered that no effect is caused on the characteristics of a semiconductor device being manufactured if the amount of the Al contaminants is not greater than 1×10¹¹ atoms/cm Thus, it is believed that the contamination of the wafer W by Al can be prevented by using the thermally sprayed Y₂O₃ coating. Moreover, as can be seen from the above-mentioned experiment data, the plasma resistance of the thermally sprayed Y₂O₃ coating is great, and, as a result, the amount of yttrium contaminants attached to the wafer W is viewed to be substantially zero, so that no influence of yttrium is considered.

(Test for Surface Roughness)

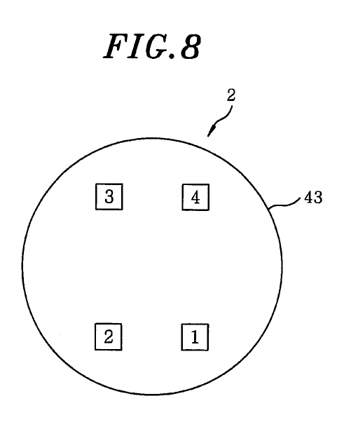

With respect to the mounting device 2 shown in FIG. 2, surface roughnesses (Ra) of four positions on the surface of the thermally sprayed Y₂O₃ coating layer 43, as shown in FIG. 8, were measured before it was used and after it had been used for two years. The results are provided in Table 2.

TABLE 2

| Measurement | | |
|---|---|---|
| point | Ra before used | Ra after used |
| 1 | 0.60 | 0.52 |
| 2 | 0.58 | 0.54 |
| 3 | 0.56 | 0.56 |
| 4 | 0.54 | 0.62 |

Though data of the thermally sprayed Y₂O₃ coating layer before used were only four, 26 data were obtained for the thermally sprayed Y₂O₃ coating layer after used (though not specified in Table 2). An average surface roughness (Ra) of the thermally sprayed Y₂O₃ coating layer 43 after used is in the range from about 0.52 μm to 0.78 μm. Accordingly, if the result of Table 2 is considered together, it is found that the average surface roughness of the thermally sprayed Y₂O₃ coating, by performing a waterless cleaning, becomes about 0.6 μm to 0.8 μm. Thus, if the average surface roughness (Ra) of the thermally sprayed Y₂O₃ coating is set to be about 0.6 μm to 0.8 μm when the electrostatic chuck is manufactured, it is possible to suppress a change of the surface roughness with a lapse of time.

(Test for Attracting Force)

An experiment was conducted, in which a 2-inch wafer was sequentially attracted to and separated from a central portion and a peripheral portion of an electrostatic chuck having a thermally sprayed Y₂O₃ coating of 250 μm formed thereon, which is used in the present invention, and attracting forces upon the separation were measured to evaluate the attracting force of the electrostatic chuck. As a result, it provides the same level of attracting force as that of an electrostatic chuck made of a 200 mm alumina ceramic plate, which is currently used in the art. Thus, it is confirmed that the electrostatic chuck of the present invention has no problem with regard to the attracting performance.

While the invention has been shown and described with respect to the embodiment, it will be understood by those skilled in the art that various changes and modifications may be made without departing from the scope of the invention as defined in the following claims.

What is claimed is:

1. A mounting device comprising:
a mounting body for sustaining a target object to be processed thereon;
an electrostatic chuck disposed on the mounting body and having an electrode layer interposed between insulating layers, the electrostatic chuck serving to electrostatically attract and hold the target object on a surface of the insulating layer by an electrostatic force generated between the electrode layer and the target object by a voltage applied to the electrode layer,
wherein an electrostatic chuck layer, which is one of the insulating layers on the side of a top surface of the electrode layer, is made of thermally sprayed coating of yttrium oxide, which is formed by a plasma spraying, having a thickness of about 200 μm to 280 μm, and the electrostatic chuck layer has a surface roughness dependent on a particle diameter of the yttrium oxide used in the plasma spraying.

2. The mounting device of claim 1, wherein an average surface roughness of the electrostatic chuck layer is about 0.6 μm to 0.8 μm.

3. The mounting device of claim 1, wherein a surface of the electrostatic chuck layer is cleaned by a plasma in a state where no target object is placed thereon.

4. The mounting device of claim 1, wherein the voltage applied to the electrode layer is equal to or greater than about 2.5 kV.

5. A plasma processing apparatus comprising:
an airtight processing vessel;
the mounting device described in any one of claims 1 to 4;
a vacuum evacuation unit for evacuating the processing vessel to vacuum; and
a plasma processing unit for performing a plasma process on the target object by generating a plasma in the processing vessel.

6. The plasma processing apparatus of claim 5, wherein a surface of the electrostatic chuck is cleaned in a state where no target object is placed on the mounting device.

7. A plasma processing method comprising:
performing a plasma processing on a target object after electrostatically attracting and holding the target object on the mounting device described in any one of claims 1 to 4; and
cleaning a surface of the electrostatic chuck by a plasma after unloading the target object from the mounting device.
